(19) United States
(12) Patent Application Publication
(10) Pub. No.: US 2023/0242811 A1
(43) Pub. Date: Aug. 3, 2023

(54) LIGHT-EMITTING ELEMENT

(71) Applicant: SHARP KABUSHIKI KAISHA, Sakai City, Osaka (JP)

(72) Inventor: Yukio TAKENAKA, Sakai City, Osaka (JP)

(21) Appl. No.: 18/008,659

(22) PCT Filed: Jun. 10, 2020
(86) PCT No.: PCT/JP2020/022874

§ 371 Date: Dec. 6, 2022

(51) Int. Cl. C09K 11/08; H10K 50/115; H10K 50/14; H10K 71/00; H10K 85/10; B82Y 30/00

(52) U.S. Cl. CPC C09K 11/0811; H10K 50/115; H10K 50/14; H10K 71/00; H10K 85/111; B82Y 30/00; H10K 2102/102

(57) ABSTRACT

A light-emitting element includes: a cathode; an anode; an EML provided between the cathode and the anode; and an ETL provided between the cathode and the EML. The ETL contains, on an interface at least to the EML, metal oxide nano particles and a polymer chemically bonding to a surface of the metal oxide nano particles. The polymer contains a main chain of a polysiloxane bond and a side chain of an organic group.

### TECHNICAL FIELD

The present disclosure relates to a light-emitting element including a carrier-transport layer containing fine particles of metal oxide.

### BACKGROUND ART

Metal oxide is higher in durability among inorganic materials, and processed in the form of nano particles and used as a carrier-transport layer of such a device as an organic light-emitting diode (OLED) or a solar cell.

However, the surface of the metal oxide nano particles typically has hydroxy groups. When these hydroxy groups come into contact with quantum dots of a quantum-dot light-emitting diode (QLED); that is, an electroluminescence device using the quantum dots to emit light, emission efficiency of the QLED decreases. This is because if the quantum dots are exposed to an electric field in which the dipole moment of the hydroxy groups is induced, excitons of the quantum dots could separate into electrons and holes. Hence, the dipole moment of the hydroxy groups separate the excitons of the quantum dots into the electrons and the holes, and possibly cause quenching (exciton quenching).

Note that such exciton quenching is likely to occur to a QLED in particular, and could occur to an OLED. The exciton quenching causes a decrease in emission efficiency.

Moreover, in a light-emitting device, if the electron-transport layer and the hole-transport layer are significantly different in mobility, the emission efficiency decreases.

Patent Document 1 discloses a technique to obtain a QLED. When aluminum (Al₂O₃) thin film having a thickness of approximately 1 nm is deposited on nickel oxide (NiO) by atomic layer deposition (ALD), exciton quenching caused on the surface of NiO by hydroxy groups is reduced. As a result, the obtained QLED is high in external quantum efficiency.

Moreover, Patent Document 2 discloses a technique: zinc oxide (ZnO) nano particles are coated with polyvinylpyrrolidone (PVP), an insulating polymer, to form an electron-transport layer of a QLED. Such a technique reduces an electron injection speed and improves a balance of the carriers.

### CITATION LIST

### Non Patent Literature

[Non Patent Document 1] Wenyu Ji, et al., “Over 800% Over 800% efficiency enhancement of all-inorganic quantum-dot light emitting diodes with an ultrathin alumina passivating layer”, Nanoscale, 2018, 10, 11103-11109
[Non Patent Document 2] Kai Sun, et al., “Blue quantum dot light emitting diodes with polyvinylpyrrolidone-doped electron transport layer”, Organic Electronics 63, 2018, 65-70

### SUMMARY OF INVENTION

### Technical Problems

However, the QLED of Patent Document 1 includes aluminum (an insulating layer), which raises drive voltage. Moreover, the QLED of Patent Document 1 requires an ALD vapor-deposition apparatus for its production, which increases production costs.

As to the QLED of Patent Document 2, the hydroxy groups on the surface of ZnO fail to disappear, and some of the hydroxy groups come into contact with the quantum dots. This could cause exciton quenching derived from the hydroxy groups on the surface of ZnO. Note that if PVP is applied more thickly, the contact between the hydroxy groups and the quantum dots could be avoided; however, in such a case, the drive voltage inevitably increases.

An aspect of the present disclosure is conceived in view of the above problems, and intended to provide a light-emitting element whose emission efficiency is higher than conventional light-emitting elements.

### Solution to Problems

In order to solve the above problems, a light-emitting element according to an aspect of the present disclosure includes: a first electrode and a second electrode; a light-emitting layer provided between the first electrode and the second electrode; and a carrier-transport layer provided between the first electrode and the light-emitting layer, wherein the carrier-transport layer contains, on an interface at least to the light-emitting layer, fine particles of metal oxide and a polymer chemically bonding to a surface of the fine particles of the metal oxide, and the polymer contains a main chain of a polysiloxane bond and a side chain of an organic group.

In order to solve the above problems, a method for producing a light-emitting element according to an aspect of the present disclosure includes; a mixture liquid preparing step of causing fine particles of metal oxide and at least one of trialkoxysilane or molecules of condensed trialkoxysilane to undergo sol-gel reaction, to prepare a mixture liquid; and a carrier-transport layer forming step of applying the mixture liquid to a position in which a carrier-transport layer is to be formed, to form the carrier-transport layer.

### Advantageous Effects of Invention

According to an aspect of the present disclosure, a polymer chemically bonds to fine particles of metal oxide. Such a feature makes it possible to remove hydroxy groups on the surface of the fine particles of the metal oxide, and to reduce exciton quenching to the hydroxy groups. Hence, an aspect of the present disclosure can provide a light-emitting element whose emission efficiency is higher than a conventional light-emitting element.

### BRIEF DESCRIPTION OF DRAWINGS

FIG. 1 collectively shows a cross-sectional view of an exemplary schematic configuration of a light-emitting element according to a first embodiment and a schematic view of an essential portion of the light-emitting element.

FIG. 2 is a flowchart sequentially showing steps of producing the light-emitting element according to the first embodiment.

FIG. 3 is a drawing schematically illustrating a step of forming an ETL at Step S11 in FIG. 2.

FIG. 4 is a cross-sectional view schematically illustrating a state of a metal oxide nano particle before undergoing sol-gel reaction.

FIG. 5 is a drawing illustrating a scheme of reaction showing hydrolysis of trialkoxysilane.

FIG. 6 is a drawing illustrating a scheme of reaction showing dehydration reaction of trisilanol.

FIG. 7 is a drawing schematically showing a scheme of reaction in which trisilanol reacts to hydroxy groups on the surface of the metal oxide nano particle, and is fixed to the surface of the metal oxide nano particle.

FIG. 8 is a drawing schematically showing a scheme of reaction in which trisilanol is fixed to the surface of the metal oxide nano particle and forms polysilsesquioxane by self-condensation.

FIG. 9 is a drawing schematically illustrating a step of forming the ETL at Step S2 in FIG. 2.

FIG. 10 is a graph showing FTIR spectra of films formed in Examples 1 and 2 and Comparative Examples 1 to 3.

FIG. 11 is a graph showing a relationship between: a volume rate of the metal oxide nano particles to a mixture film forming the ETL; and an inter-nanoparticle distance between the metal oxide nanoparticles adjacent to one another.

FIG. 12 is a cross-sectional view illustrating an exemplary schematic configuration of a light-emitting element according to a second embodiment.

FIG. 13 is a cross-sectional view illustrating an exemplary schematic configuration of a light-emitting element according to a third embodiment.

FIG. 14 is a cross-sectional view illustrating an exemplary schematic configuration of a light-emitting element according to a fourth embodiment.

### DESCRIPTION OF EMBODIMENTS

### First Embodiment

Described below are embodiments of the present disclosure. Note that, in the description below, the term “layer below” means that a layer is formed in a previous process before a comparative layer is formed. The term “layer above” means that a layer is formed in a successive process after a comparative layer is formed. Moreover, in this disclosure, the statement “A to B” regarding two numbers A and B means “A or more and B or less” unless otherwise specified.

Schematic Configuration of Light-Emitting Element

A light-emitting element according to this embodiment includes: a first electrode; a second electrode; a light-emitting layer (hereinafter referred to as “EML”) provided between the first electrode and the second electrode; and a first carrier-transport layer provided between the first electrode and the EML and serving as a carrier-transport layer. Described below as an example is a case where the first electrode is a cathode, the second electrode is an anode, and the first carrier-transport layer is an electron-transport layer (hereinafter referred to as “ETL”).

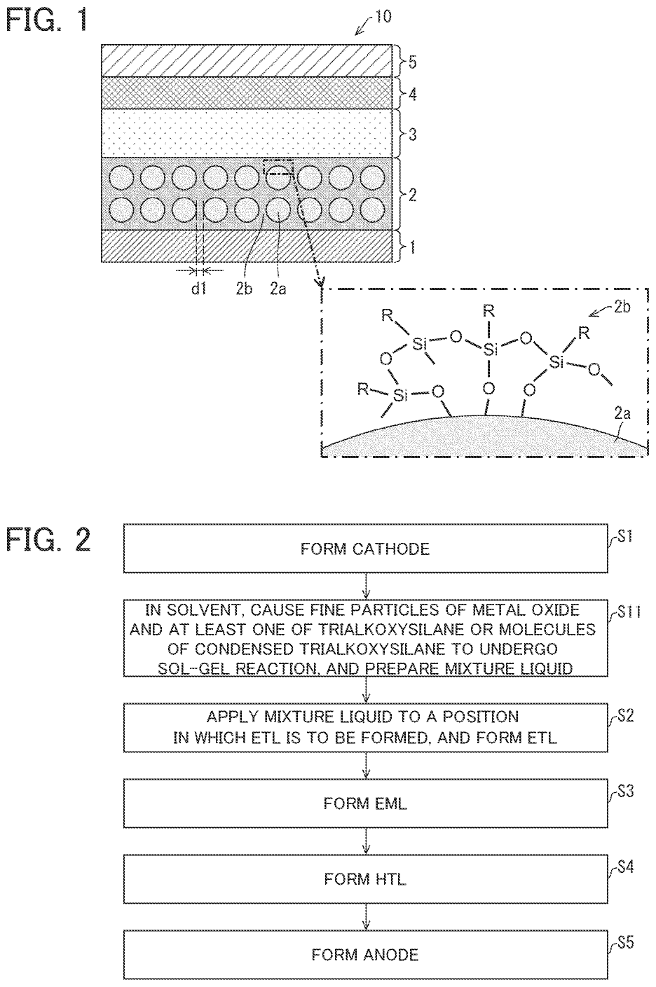

FIG. 1 collectively shows a cross-sectional view of an exemplary schematic configuration of a light-emitting element 10 according to this embodiment and a schematic view of an essential portion of the light-emitting element 10.

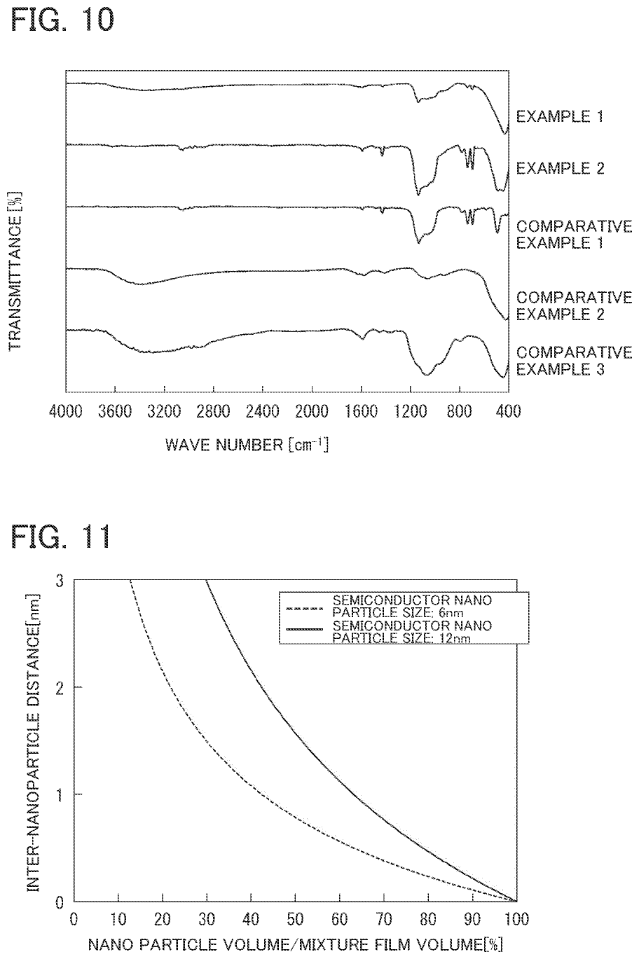

The light-emitting element 10 illustrated in FIG. 10 includes: a cathode 1; an ETL 2; an EML 3; and an anode 5, all of which are stacked one another in this order from below.

In the example in FIG. 1, the cathode 1 is a lower electrode provided below, and the anode 5 is an upper electrode provided above. In this embodiment, a direction from the cathode 1 toward the anode 5 is referred to as the upward direction. Moreover, a direction opposite to the upward direction is referred to as the downward direction.

Note that, as illustrated in FIG. 1, between the EML 3 and the anode 5 serving as the second electrode, a hole-transport layer (hereinafter referred to as “HTL”) 4 may be provided as a second carrier-transport layer. Described below as an example is a case where the cathode 1, the ETL 2, the EML 3, the HTL 4, and the anode 5 are stacked one another in this order from below.

Moreover, typically, the lower electrode is formed on a substrate as a support body for forming a light-emitting element. Hence, the light-emitting element 10 may include a not-shown substrate as the support body. In such a case, the substrate included in the light-emitting element 10 may be, for example, a glass substrate or such a flexible substrate as a resin substrate. Note that if the light-emitting element 10 is a part of a light-emitting device such as a display device, the substrate is of the light-emitting device. Hence, the substrate may be, for example, an array substrate on which a plurality of thin-film transistors are formed. In such a case, the lower electrode is electrically connected to a thin-film transistor of the array substrate.

Note that the substrate may be formed of either a light-transparent material or a light-reflective material. Note that if the light-emitting element 10 has either a bottom-emission structure or a double-sided-emission structure, the substrate is a light-transparent substrate made of a light-transparent material.

The cathode 1 injects electrons through the ETL 2 into the EML 3. Meanwhile, the cathode 5 injects holes through the HTL 4 into the EML 3.

The cathode 1 and the anode 5 are each made of a conductive material. The cathode 1 may have a function of the hole-injection layer (HIL) to inject the holes into the ETL 2. The anode 5 may have a function of the electron-injection layer (EIL) to inject the electrons into the HTL 4.

Moreover, of the cathode 1 and the anode 5, an electrode from which light is released needs to be transparent to light. Meanwhile, the electrode across from which light is released may be either light-transparent or light-reflective.

Hence, at least one of the cathode 1 or the anode 5 is made of a light-transparent material. Moreover, either the cathode 1 or the anode 5 may be formed of a light-reflective material.

The light-transparent material may be, for example, a transparent conductive film material. The transparent conductive film material may be, for example, indium tin oxide (ITO) or indium zinc oxide (IZO).

The light-reflective material is preferably a material highly reflective to visible light. The light-reflective material may be, for example, a metal such as aluminum (Al), copper (Cu), gold (Au), or silver (Ag). Alternatively, the light-reflective material may be an alloy containing these metals.

Moreover, either the cathode 1 or the anode 5 may be a multilayer stack including a light-transparent material and a light-reflective material, so that either the cathode 1 or the anode 5 may be a light-reflective electrode.

The EML 3 contains a light-emitting material, and serves as a layer to emit light by recombination of the electron transported from the cathode 1 and the holes transported from the anode 5.

The EML 3 contains, as a light-emitting material, for example, nano-sized quantum dots (semiconductor nano particles). The quantum dots may be known quantum dots. The quantum dots may contain at least one semiconductor material made of at least one element selected from the group consisting of, for example: cadmium (Cd); sulfur (S); tellurium (Te); selenium (Se); zinc (Zn); indium (In); nitrogen (N); phosphorus (P); arsenic (As); antimony (Sb); aluminum (Al); gallium (Ga); lead (Pb); silicon (Si); germanium (Ge); and magnesium (Mg). Moreover, the quantum dots may be of a two-component core type, a three-component core type, a four-component core type, a core-shell type, or a core-multishell type. Furthermore, the quantum dots may contain nano particles doped with at least one of the above elements, and have a compositional gradient.

The HTL 4 is a layer to transport the holes to the EML 3. Note that the HTL 4 may also function to block transportation of the electrons.

The HTL 4 contains a hole-transporting material. In this embodiment, the hole-transporting material is an organic hole-transporting material. Examples of the organic hole-transporting material include, for example: poly(3,4-ethylenedioxythiophene)-poly(4-styrene sulfonate) (PEDOT: PSS); polyvinylcarbazole (PVK); and poly[(9,9-dioctylfluorenyl-2,7-diyl)-co-(4,4′-(N-(4-sec-butylphenyl)diphenylamine)] (TFB). One of these hole-transporting materials may be used alone, or two or more of these hole-transporting materials may be used in combination as appropriate.

The ETL 2 is a layer to transport the electrons to the EML 3. The ETL 2 is provided in contact with the EML 3. Note that the ETL 2 may also function to block transportation of the holes.

The ETL 2 contains, as boxed with a dot-and-dash line in FIG. 1, metal oxide nano particles (fine particles of metal oxide) 2a that transport carriers, and a polymer 2b chemically bonding to the metal oxide nano particle 2a.

Examples of the metal oxide include: zinc oxide (e.g. ZnO); nickel oxide (e.g. NiO); magnesium oxide (e.g. MgO); copper oxide (e.g. CuO and CuzO); molybdenum oxide (e.g. MoO₂, MoO₃); tin oxide (e.g. SnO and SnO₂); titanium oxide (e.g. TiO₂); vanadium oxide (e.g. VO₂ and V₂O₅); tungsten oxide (e.g. WO₂ and WO₃); niobium oxide (e.g. Nb₂O₅); indium oxide (e.g. In₂O₃); and cerium oxide (e.g. CeO₂). One of these metal oxides may be used alone. Alternatively, two or more of these metal oxides may be used in combination as appropriate. A mixed crystal of these metals may be used.

Hence, the metal oxide nano particles 2a may contain nano particles (fine particles) of: at least one metal oxide selected from the group consisting of zinc oxide, nickel oxide, magnesium oxide, copper oxide, molybdenum oxide, tin oxide, titanium oxide, vanadium oxide, tungsten oxide, niobium oxide, and indium oxide; or a mixed crystal of the metal oxides.

In this embodiment, the metal oxide nano particles 2a are preferably wide-gap metal oxide nano particles capable of transporting electrons. Hence, the metal oxide nano particles 2a are preferably nano particles of: such metal oxides as zinc oxide, titanium oxide, tin oxide, and cerium oxide among the above metal oxides; or a metal oxide included in these metal oxides and doped with another metal element. Note that the nano particles of such a metal oxide as zinc oxide, titanium oxide, tin oxide, or cerium oxide doped with another metal element are nano particles of such a metal oxide as zinc magnesium oxide (ZnMgO), strontium titanate (SrTiO₃), or antimony zinc oxide (AZO).

The metal oxide nano particles 2a shall not be limited to particular nano particles in terms of shape and size. Preferably, the metal oxide nano particles 2a may have a spherical shape and a median particle size (diameter) ranging from 0.5 to 20 nm. If the median particle size (diameter) of the metal oxide nano particles 2a is excessively large, the surface roughness of a deposited nano particle film is large and the concentration of an electrical field is likely to occur. Hence, in view of the smoothness of the deposited nano particle film, the median particle size is desirably 20 nm or less. Note that, if the median particle size is excessively small, the carriers are less likely to be transported and the metal oxide nano particles 2a are more likely to agglomerate. Hence, the median particle size is desirably 0.5 nm or more.

Note that, in this disclosure, the median particle size of the nano particles can be measured by dynamic light scattering when the nano particles are in a solution and with a transmission electron microscope (TEM) when the nano particles are in a thin film, regardless of the kind of the nano particles. In this disclosure, the median particle size of the nano particles is a diameter of the nano particles at 50% of an integrated value in the particle size distribution.

The polymer 2b is a compound containing: a main chain of a siloxane bond (a Si—O bond) representing a bond of a silicon atom (a Si atom) and an oxygen atom (an O atom); and a side chain of an organic group (an organic functional group). The above organic group is directly bonded to the Si atom of the siloxane bond.

Preferably, the polymer 2b contains a main chain of the siloxane bond, and the Si atom of the siloxane bond is a T-body Si atom bonding to three oxide atoms and the organic group. This polymer 2b is a polymer containing a main chain of the siloxane bond as a repeating unit. That is, the main chain of the polymer 2b may contain a repetition of the siloxane bond having a Si atom and O atoms alternately bonding together; and the side chain of the polymer 21b may contain an organic group.

The polymer 2b may have any given weight-average molecular weight. In the solution, in view of the solubility of the polymer 2b in the solvent, the weight-average molecular weight preferably ranges 1000 or above and 10000 or below. After the film is deposited and heated, the weight-average molecular weight is desirably 10000 or more.

Examples of the polymer 2b include polysilsesquioxane (hereinafter referred to as “PSQ”) and silsesquioxane of a random-type (a random-structure) represented by a structural formula (1) below.

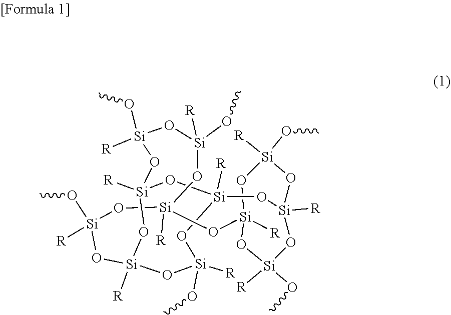

The polymer 2b may be a random copolymer whose precursor contains: trialkoxysilane; and at least one of tetraalkoxysilane or dialkoxysilane at a molar rate of 20% or less with respect to trialkoxysilane. Moreover, the polymer 2b may contain cyclic siloxane.

Furthermore, the polymer 2b may be a mixture of PSQ and another polymer. For example, in the solution, PSQ may be polymerized together with the metal oxide nano particles 2a, and after that, mixed with another polymer at a weight rate of 20% or less with respect to PSQ to adjust mobility of the carriers. Examples of the other polymer include: such insulating polymers as polymethyl methacrylate (PMMA), and polyvinylpyrrolidone (PVP); and such conductive polymers as poly[(9,9-dioctylfluorenyl-2,7-diyl)-co-(4,4′-(N-(4-sec-butylphenyl)diphenylamine)] (TFB), and polyvinylcarbazole (PVK). One of the above other polymers may be mixed alone with PSQ. Alternatively, two or more of the above other polymers may be mixed with PSQ.

Note that, in structural formula (1), each R is an independent side chain and represents an organic group. The organic group (R) may be any given organic group. The larger the number of carbons (the number of molecules, from another viewpoint) of the organic group is, the longer the distance is between the metal oxides in the carrier-transport layer. As a result, the carriers are less likely to be transported between the metal oxide particles. Hence, the organic group (R) is selected preferably from functional groups having a small number of carbons and molecules. Thus, the organic group (R) is preferably an organic group with 10 or less carbons, and, more preferably, an organic group with 1 or more and 5 or less carbons.

Moreover, the organic group (R) is preferably a stable functional group. The organic group (R) is preferably a non-reactive functional group unsusceptible to hydrolysis. Specifically, the organic group (R) does not preferably contain: a hydroxy group or a carboxyl group that reacts to a silanol (—SiOH) group of a siloxane bond; or an ester bond that undergoes hydrolysis.

Examples of the organic group (R) include such hydrocarbon groups as an alkyl group and an aryl group. The organic group (R) may have either a substituent or a hetero atom. That is, examples of the organic group (R) include such hydrocarbon groups as an alkyl group and an aryl group either having no substitute or having one of a substituent or a hetero atom. Examples of the substituent include at least one functional group selected from the group consisting of a methyl group, an ethyl group, an amino group, a mercapto group, a vinyl group, and a fluoro group. Moreover, examples of the hetero atom include at least one atom selected from the group consisting of nitrogen, sulfur, oxygen, and boron.

Among the above substances, the organic group (R) is preferably at least one selected from the group consisting of an alkyl group, an aminoalkyl group, a mercaptoalkyl group, a vinylalkyl group, a fluoroalkyl group, an aryl group, and a heteroaryl group, each of which has carbons or less.

Note that each of the aryl group and the heteroaryl group may be formed in either a monocyclic ring or a fused (condensed) ring. The aryl group is preferably at least one selected from the group consisting of: an aryl group formed in any one of a five-membered ring, a six-membered ring, and a seven-membered ring; a fused ring of the above aryl group; a derivative of the aryl group; and a derivative of the fused ring of the aryl group. Moreover, the heteroaryl group is preferably at least one selected from the group consisting of: a heteroaryl group formed in any one of a five-membered ring, a six-membered ring, and a seven-membered ring, and containing at least one kind of one to three hetero atoms selected from the group consisting of nitrogen, sulfur, oxygen, and boron; a fused ring of the heteroaryl group, a derivative of the heteroaryl group; and a derivative of the fused ring of the above heteroaryl group. Examples of the heteroaryl group include a nitrogen-containing heteroaryl group, a sulfur-containing heteroaryl group, an oxygen-containing heteroaryl group, and a boron-containing heteroaryl group. As to these nitrogen-containing heteroaryl group, sulfur-containing heteroaryl group, oxygen-containing heteroaryl group, and boron-containing heteroaryl group, at least one of a methane group (—CH ═) group or a vinylene (—CH═CH—) group contained in the aryl groups may be substituted for one to three nitrogen atoms, sulfur atoms, oxygen atoms, or boron atoms.

Furthermore, as described above, the organic group (R) may have a substituent or a hetero atom; however, the organic group (R) may be more preferably an alkyl group or an aryl group with no substituent. Of the alkyl group or the aryl group, particularly preferable is an alkyl group or a phenyl group with one to five carbons.

An example of PSQ described above includes polyphenylsilsesquioxane (hereinafter referred to as “PPSQ”) whose organic group (R) is a phenyl group, or polymethylsilsesquioxane whose organic group (R) is a methyl group.

The polymer 2b preferably contains PSQ. More preferably, the polymer 2b is PSQ. PSQ is a collective term of polysiloxane having a T-body Si atom; that is, a Si atom of a siloxane bond is bonded to three oxygen atoms, and each of the Si atoms has one organic group.

As illustrated in FIG. 1, PSQ desirably has a silsesquioxane skeleton in a random structure. However, PSQ shall not be limited to the one having such a random structure. PSQ may have a silsesquioxane skeleton in a soluble ladder structure having a regular molecular structure and a higher order structure. Moreover, PSQ having a silsesquioxane skeleton in a basket-shaped structure may be contained in the random structure.

As will be described later, a starting material of the polymer 2b undergoes hydrolysis so that the polymer 2b generates a silanol (—SiOH) group. This silanol group undergoes dehydration condensation reaction together with the hydroxy group on the surface of the metal oxide nano particles 2a, and further undergoes self-condensation. Hence, the metal oxide nano particles 2a and the polymer 2b are composited to form a composite in which the polymer 2b coats the metal oxide nano particles 2a.

As boxed with a dot-and-dash line in FIG. 1, the polymer 2b bonds to the surface of a metal oxide nano particle 2a by siloxane bonding. The polymer 2b chemically bonds to, and forms a composite with, the metal oxide nano particle 2a. Note that the polymer 2b may form a composite with a plurality of the metal oxide nano particles 2a. Specifically, for example, one PSQ may chemically bond to a different metal oxide nano particle 2a.

Moreover, as described above, the polymer 2b includes a polymer having a basic configuration unit of the T-unit (—RSiO₃—) in which a Si atom of a siloxane bond is bonded to three oxygen atoms and the organic group (R). Hence, the polymer 2b forms a coating to coat the metal oxide nano particle 2a.

The ETL 2 is made of a mixture film containing the metal oxide nano particles 2a and the polymer 2b that form a composite. Preferably, the ETL 2 is formed of a sedimentary layer of a composite containing the metal oxide nano particles 2a and the polymer 2b.

A volume ratio of the metal oxide nano particles 2a to the mixture film (more specifically, a volume ratio of the metal oxide nano particles 2a to a sum of the metal oxide nano particles 2a and the polymer 2b) will be described later.

Note that a thickness of each of the layers in the light-emitting element 10 can be set as is conventionally set, and shall not be limited to a particular thickness. For example, the carrier-transport layers (the ETL 2 and the HTL 4) each have a thickness set within a range of 2 nm or more and 500 nm or less. If each layer is thin, a short circuit due to pin holes is likely to occur, and if each layer is thick, the drive voltage rises. Hence, each layer has a thickness desirably within a range of 2 to 500 nm, and, more desirably, 20 to 50 nm.

Method for Producing the Light-Emitting Element 10

Next, an exemplary method for producing the light-emitting element 10 will be described below. FIG. 2 is a flowchart sequentially showing steps of producing the light-emitting element 10 according to this embodiment.

As illustrated in FIGS. 1 and 2, in the steps of producing the light-emitting element 10 according to this embodiment, first, the cathode 1 is formed on a not-shown substrate (Step S1: a first electrode forming step). The cathode 1 can be formed by conventionally known various kinds of cathode forming techniques such as, for example, sputtering, vacuum vapor deposition, chemical vapor deposition (CVD), plasma CVD, and printing.

Meanwhile, in the solvent, the metal oxide nano particles 2a and at least one of trialkoxysilane or molecules (a composite) of condensed trialkoxysilane undergo sol-gel reaction. Hence, a mixture liquid (sol) is prepared as an ETL material (a carrier-transport material) (Step S11: a mixture liquid preparing step). Trialkoxysilane and the molecules of condensed trialkoxysilane are soluble even if polymerized to some degree, and bond to the surface of such an oxide as the metal oxide nano particles 2a.

Next, the mixture liquid prepared at Step S11 is applied to a position, on the cathode 1, in which the ETL 2 is to be formed. The applied mixture liquid is dried to form the ETL 2 (i.e. the ETL 2 is stacked) (Step S2: a first carrier-transport layer forming step). Note that the mixture liquid can be applied by, for example, sputtering, the CVD, or spin-coating. The technique to form the ETL 2 will be described later in more detail.

Next, on the ETL 2, the EML 3 is formed (stacked) in contact with the ETL 2 (Step S3: a light-emitting layer forming step). In forming the EML 3, conventionally known various kinds of techniques can be used as techniques to form an EML. Examples of the techniques to form the EML include: vapor deposition; printing; ink-jet printing; spin-coating; casting; dipping; bar-coating; blade-coating; roll-coating; gravure-coating; flexography; spray-coating; photolithography; and self-organization coating (layer-by-layer coating, self-assembled monolayer coating).

After that, on the ETL 3, the HTL 4 is formed (stacked) as necessary (Step S4: a second carrier-transport layer forming step). In forming the HTL 4, conventionally known various kinds of techniques, such as, for example, sol-gel process, sputtering, the CVD, spin-coating, and dip-coating can be used as techniques to form an HTL.

Then, the anode 5 is formed (stacked) (Step S5: a second electrode forming step). In forming the anode 5, conventionally known various kinds of techniques can be used as techniques to form an anode. Specifically, the anode 5 can be formed by the same technique as the cathode 1 is formed. By the above method, the light-emitting element 10 can be produced.

Technique to Form ETL 2

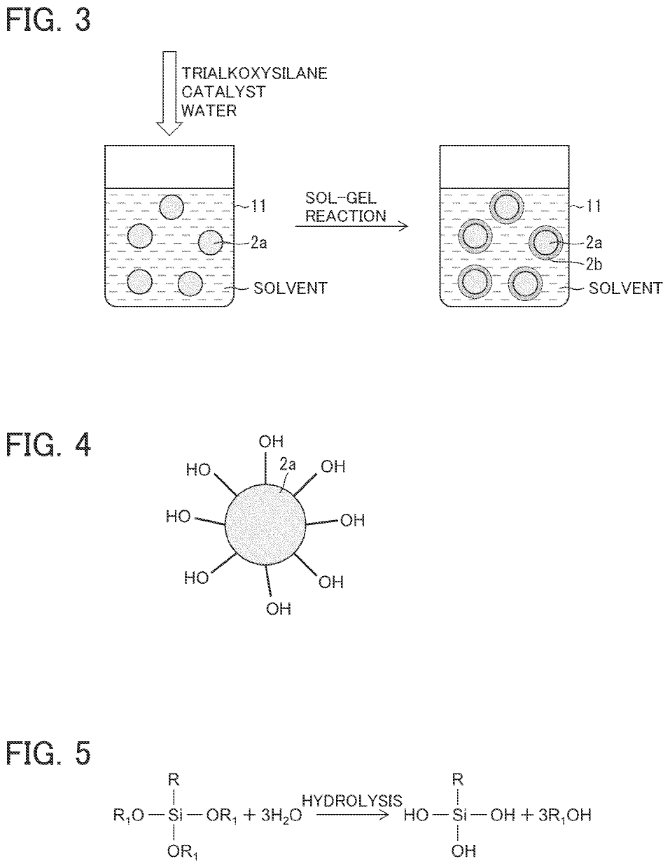

Next, Steps S11 and S2 will be described in more detail, with reference to FIGS. 3 to 9.

FIG. 3 is a drawing schematically illustrating a step of forming the ETL 2 at Step S11 in FIG. 2.

As described before, at the step of forming the ETL 2, first, Step S11 is carried out. At Step S11, as illustrated in FIG. 3, in the solvent, the metal oxide nano particles 2a and at least one of trialkoxysilane or molecules of condensed trialkoxysilane undergo sol-gel reaction. Hence, a mixture liquid (sol) is prepared as an ETL material.

In the sol-gel reaction, hydrolysis is carried out in the solution. After that, dehydration condensation reaction is carried out, so that the solution is transformed to the sol. After that, the reaction is further allowed to proceed, so that the sol is transformed to a gel.

Hence, at Step S1, as illustrated in FIG. 3, first, a fluid disperse including a solvent and the metal oxide nano particles 2a dispersed into the solvent, a monomer serving as a starting material of the polymer 2b, and water and a catalyst for hydrolysis are added to a reaction container 11. Then, the reaction container 11 is sealed. The mixture is stirred, and the monomer undergoes hydrolysis. For stirring, various kinds of known stirring apparatuses can be used.

The catalyst to be preferably used is an acid catalyst such as formic acid, hydrochloric acid, or nitric acid.

Moreover, the above solvent to be used is an alcohol solvent such as ethanol or an organic solvent such as toluene.

The monomer serving as the starting material of the polymer 2b is trialkoxysilane; that is, trifunctional alkoxysilane. Trialkoxysilane has a T-body Si atom bonding to three oxygen atoms and an organic group. The organic group is the organic group (R).

Note that, if the monomer to be used is either dialkoxysilane having a D-body Si atom bonding to two oxygen atoms, or tetraalkoxysilane having a Q-body Si atom bonding to four oxygen atoms, the problems below would arise.

First, the precursor not having a reactive functional group and essentially containing dialkoxysilane does not solidify even if polymerized. The film finally obtained (specifically, a mixture film containing the metal oxide nano particles 2a and a polymer serving as the polymer 2b and made of the precursor) is not a solid.

Dialkoxysilane, having such a reactive functional group as an acrylic group or an epoxy group, can solidify with a polymeric initiator mixed together with a polymer. However, the problem is, if the polymeric initiator remains in the device, the durability of the device decreases. Hence, dialkoxysilane is not preferable.

Moreover, if a polymer made of a precursor essentially containing tetraalkoxysilane is heated in its production process, most of the hydroxy groups derived from tetraalkoxysilane does not disappear. Hence, it is impossible to achieve advantageous effects of removing the hydroxy groups and reducing a rise of the drive voltage.

Hence, the polymer made of the precursor essentially containing dialkoxysilane or tetraalkoxysilane cannot be used as the carrier-transport layer even though the polymer can coat the metal oxide nano particles 2a.

Note that, the monomer may contain at least one of dialkoxysilane or tetraalkoxysilane if dialkoxysilane or tetraalkoxysilane is at a molar rate of 30% or less with respect to trialkoxysilane.

Note that, when trialkoxylilanes in different kinds are mixed together in a state of the monomer, a random copolymer can be obtained on the same synthesis condition as a single trialkoxylilane is used.

An amount of the catalyst added to the monomer may be a sufficient amount of the catalyst for hydrolysis of the monomer. In view of reaction speed of the hydrolysis, the amount of the catalyst ranges preferably from 0.1 to 10 wt %.

In the solvent, a concentration of the metal oxide nano particles 2a preferably ranges from 1 to 100 mg/ml, because the metal oxide nano particles 2a agglomerate together at a high concentration.

A rate of the mixed monomer with respect to the metal oxide nano particles 2a is the same as the volume rate of the polymer 2b to the metal oxide nano particles 2a in the finally obtained mixture film. If the mixture film is made of a composite including the metal oxide nano particles 2a and the polymer 2b, the mixture rate of the monomer (i.e. the volume of the polymer 2b with respect to the volume of the metal oxide nano particles 2a) is defined as a volume ratio of the metal oxide nano particles 2a to the mixture film. Note that, as described before, the volume ratio of the metal oxide nano particles 2a to the mixture film will be described later.

Note that the water to be used for the hydrolysis may be water equal in molar amount to the alkoxy group in the monomer.

Moreover, in the hydrolysis, a reaction temperature and a reaction time may be set appropriately to finish the reaction (i.e. the hydrolysis). Hence, the reaction temperature shall not be limited to a particular temperature. In view of the speeds of the hydrolysis and polymerization reaction, the reaction temperature ranges preferably from 0 to 100° C. Moreover, the reaction time preferably ranges from 1 to 48 hours so that the hydroxy group on the surface of the metal oxide nano particles 2a sufficiently undergoes the hydrolysis.

FIG. 4 is a cross-sectional view schematically illustrating a state of a metal oxide nano particle 2a before undergoing the sol-gel reaction. As described before, metal oxide is particularly higher in durability among inorganic materials. However, on the surface of the metal oxide, a metal ion Mⁿ⁺ and an oxygen ion O²⁻ are present. These ions react with water molecules (H₂O molecules) around, readily transforming the surface to a hydroxy group. Hence, as illustrated in FIG. 4, the surface of the metal oxide nano particle 2a is covered with hydroxy groups.

FIG. 5 is a drawing illustrating a scheme of reaction showing hydrolysis of trialkoxysilane. Note that, in FIG. 5, R represents the organic group (R). Each R₁ is independent, and represents an alkyl group with 1 to 10 carbons.

Examples of the trialkoxysilane include: phenyltrimethoxysilane; phenyltriethoxysilane; 3-aminopropyltriethoxysilane; 3-carbazolylpropyltriethoxysilane; 3-mercaptopropyltriethoxysilane; and 3,3,3-trifluoropropyltriethoxysilane.

As illustrated in FIG. 5, when trialkoxysilane undergoes hydrolysis with an acid catalyst or a base catalyst, silane is obtained. The obtained silane has some or all of alkoxy (—OR₁) groups transformed to hydroxy groups (silanol groups). When a trialkoxy group transforms to the hydroxy group, dehydration condensation reaction is likely to occur. Note that a hydrocarbon group, such as an alkyl group, directly bonds as the organic group (R) to a Si atom without through an O atom does not undergo the hydrolysis.

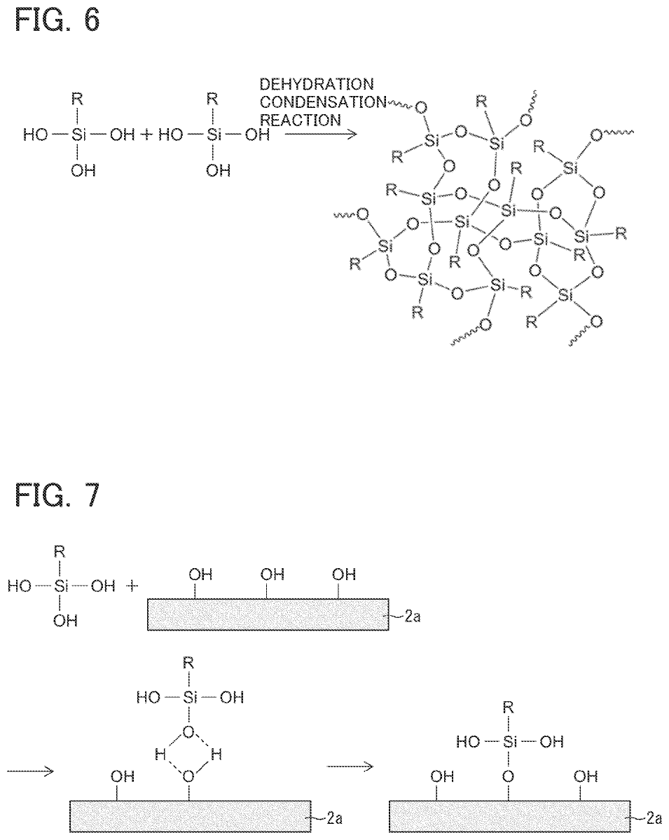

FIG. 6 is a drawing illustrating a scheme of reaction showing a dehydration reaction, of trisilanol, in which all the trialkoxy groups of trialkoxysilane transform to hydroxy groups, as an example of silane having a hydroxy group.

After the hydrolysis of trialkoxysilane illustrated in FIG. 5, the dehydration condensation reaction proceeds. As illustrated in FIG. 6, PSQ represented by the structural formula (1) is obtained.

FIG. 7 is a drawing schematically showing, as an example, a scheme of reaction in which trisilanol, obtained by the hydrolysis of trialkoxysilane in FIG. 5, reacts to hydroxy groups on the surface of the metal oxide nano particle 2a, and is fixed to the surface of the metal oxide nano particle 2a.

As illustrated in FIG. 5, when trialkoxysilane undergoes the hydrolysis, and a silanol group (—SiOH) is generated, this silanol group is adsorbed to a hydroxy group on the surface of the metal oxide nano particle 2a as illustrated in FIG. 7. After that, the surface is treated with, for example, heat. The silanol group, which is adsorbed to the hydroxy group on the surface of the metal oxide nano particle 2a, forms a siloxane bond by dehydration condensation reaction. Then, the silanol group is fixed to the surface of the metal oxide nano particle 2a. This is how the hydroxy group can disappear from the surface of the metal oxide nano particle 2a.

Meanwhile, as illustrated in FIG. 6, trisilanol obtained by the hydrolysis of trialkoxysilane forms PSQ by self-condensation.

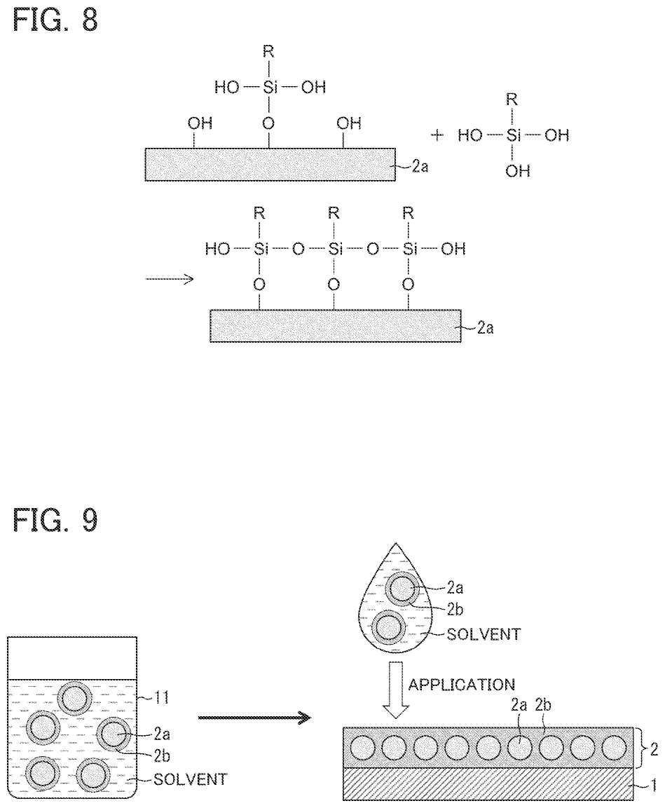

FIG. 8 is a drawing schematically showing a scheme of reaction in which trisilanol, obtained by the hydrolysis of trialkoxysilane, is fixed to the surface of the metal oxide nano particle 2a and forms PSQ by self-condensation.

As illustrated in FIG. 8, trisilanol obtained by the hydrolysis of trialkoxysilane is, for example, heated, and undergoes dehydration condensation reaction together with a hydroxy group on the surface of the metal oxide nano particle 2a. Meanwhile, trisilanols themselves (i.e. silanes themselves having hydroxy groups) undergo dehydration condensation reaction together. Hence, on the surface of the metal oxide nano particle 2a, PSQ or trisilanol (such as a monomer or an oligomer) serving as a precursor of PSQ is fixed.

The dehydration condensation reaction proceeds at a room temperature. However, the dehydration condensation reaction proceeds quickly when heat is added. Hence, the condensed PSQ may be heated at a temperature below a thermal decomposition temperature, so that the dehydration condensation reaction may be induced. PSQ, the organic group (R) of which is either a methyl group or a phenyl group, has a thermal decomposition temperature of 450° C. Hence, at Steps S11 and S2, the mixture liquid may be heated at a temperature below 450° C. A characteristic of PSQ is that, when heated, PSQ further polymerizes, and solidifies and becomes insoluble. In this embodiment, the mixture liquid is heated at a temperature below 450° C., so that polymerization of at least one of trialkoxysilane or molecules of condensed trialkoxysilane (trisilanol as a precursor) is promoted. Hence, the polymer 2b to be obtained (PSQ) is solidified and becomes insoluble. Such a feature can protect the organic group (R) to reduce the risks of decomposition of the methyl group or the phenyl group by heat, and the resulting formation of silica. In addition, the feature can quickly promote the dehydration condensation reaction.

Note that a catalyst used for the dehydration condensation reaction may be the same catalyst used for the hydrolysis. Hence, the mixture liquid to be used for the dehydration condensation reaction may contain the catalyst (specifically, the acid catalyst) used for the hydrolysis. Moreover, the solvent to be used for the dehydration condensation reaction can be the same as the solvent used for the hydrolysis. Hence, the dehydration condensation reaction may be directly followed by the dehydration condensation reaction.

Note that the dehydration condensation reaction proceeds, maintaining the concentration of the metal oxide nano particles 2a in the solvent and the concentrations of PSQ and a compound serving as a precursor of PSQ. Hence, after the hydrolysis, the reaction container I1 is open and the solvent is delivered in the form of droplets. While the concentration of the metal oxide nano particles 2a and the concentrations of PSQ and the compound serving as the precursor of PSQ are maintained, the catalyst and the water are evaporated.

The reaction time may be set appropriately to any given time to finish the reactions. Preferably, the reaction time ranges from 1 to 48 hours so that the hydroxy groups on the surface of the metal oxide nano particles 2a sufficiently react to the hydroxy group of PSQ.

Thanks to the above reactions, the mixture liquid (sol) is obtained as illustrated in FIG. 3. The mixture liquid contains a composite including the metal oxide nano particles 2a and the polymer 2b. As the polymer 2b, PSQ chemically bonds to the surface of the metal oxide nano particles 2a. Here, as described before, PSQ, which is solidified and soluble, is fixed to the surface of the metal oxide nano particles 2a.

In the mixture liquid (sol), a weight-average molecular weight of the polymer 2b or of a composite (an oligomer) serving as a precursor of the polymer 2b is preferably 10000 or less. If the weight-average molecular weight is approximately 10000 or less, the polymer 2b or the composite is soluble in such an above solvent as toluene or alcohol. The mixture liquid (sol) can be used as a coating liquid.

When the polymer 2b and the precursor of the polymer 2b, which is either a monomer or an oligomer, are subjected to the dehydration condensation reaction to form a macromolecule, the polymer 2b and the precursor become a polymer thin film; that is, a PSQ thin film, insoluble to the solvent. Hence, at Step S2, when the mixture liquid containing the composite is applied and subjected to the dehydration condensation reaction, a film is formed of the metal oxide nano particle 2a coated with the polymer 2b.

FIG. 9 is a drawing schematically illustrating a step of forming the ETL 2 at Step S2 in FIG. 2.

As illustrated in FIG. 9, at Step S2, the mixture liquid (sol) formed at Step S11 and containing the compound of the metal oxide nano particles 2a and the polymer 2b is applied to a position, on the cathode 1, in which the ETL 2 is to be formed. Then, the mixture liquid (sol) is, for example, calcined, and the dehydration condensation reaction is finished, so that the sol transforms to a gel (a macromolecule). Moreover, the solvent is completely removed from the gel and the gel is dried. Hence, the compound is solidified. Thus, as the ETL 2, a film is formed of the compound containing the metal oxide nano particles 2a and the polymer 2b.

PSQ is highly durable and coatable. In this embodiment, the oxide metal nano particles 2a, which are coated with the highly durable and coatable PSQ, are used for the ETL 2.

### Advantageous Effects

As can be seen, this embodiment uses metal oxide, which is higher in durability among inorganic materials, for a carrier-transport layer (i.e. the ETL 2 in the example of FIG. 1). Moreover, in this embodiment, a passivation layer made of an insulating layer is not deposited on the carrier-transport layer. A compound, containing the metal oxide nano particles 2a capable of transporting the carriers and the polymer 2b with insulating properties, is used as the carrier-transport layer. The polymer 2b chemically bonds to the metal oxide nano particles 2a, and forms a thin and insulating polymer coat. Furthermore, this embodiment can provide a portion in which the metal oxide nano particles 2a and the EML 3 are directly in contact with each other. Hence, in this embodiment, unlike the case where an insulating layer is sandwiched between the carrier-transport layer and the EML 3, the drive voltage does not rise. Such a feature makes it possible to produce a device with a low drive voltage.

In addition, unlike Patent Document 1, this embodiment does not require an ALD vapor-deposition apparatus, making it possible to readily form the carrier-transport layer in the application process as described above. Such a feature can reduce production costs.

Moreover, as described in Patent Document 2, if the metal oxide nano particles are simply coated with an insulating polymer, the hydroxy groups on the surface of the metal nano particles fails to disappear. This is not limited to PVP as described in Patent Document 2. The same is true of the cases where the surface of the metal oxide nano particles is coated with polysiloxane previously formed as a macromolecule, or with coating fine particles formed of a polymer solidified and pulverized. In either case, the hydroxy groups come into contact with the EML, and, as described before, exciton quenching occurs.

However, in this embodiment, as illustrated in FIGS. 7 and 8, the metal oxide nano particles 2a and the precursor of the polymer 2b chemically react and bond together, making it possible to remove the hydroxy group almost completely. Hence, even if the EML 3 (i.e. quantum dots if the EML 3 is a quantum-dot light-emitting layer) is close to the metal nano particles 2a, exciton quenching does not occur, making it possible to increase emission efficiency.

Furthermore, according to this embodiment, the surface of the metal oxide nano particles 2a is coated with the polymer 2b. Such a feature can reduce a speed of injecting the carriers (in this embodiment, a speed of injecting the electrons). Note that if the organic group (R) is a functional group (e. g. an aryl group) having a n-conjugated electron, hopping conduction of carriers caused by the n-conjugated electron is expected. Hence, mobility of the carriers can be improved. Thus, according to this embodiment, the mobility of the carriers can be controlled to improve a balance of the carriers. Hence, from such a viewpoint, the emission efficiency can be improved.

Moreover, the metal oxide nano particles 2a are highly durable themselves. Furthermore, according to this embodiment, the surface of the metal oxide nano particles 2a is coated with the polymer 2b. Such a feature allows the ETL 2 to be deposited better, making it possible to reduce pinholes. Thus, a highly durable carrier-transport layer can be formed. Accordingly, the light-emitting element 10 finally obtained can improve in durability. Furthermore, it is known that typical metal oxide nano particles agglomerate due to temporal change after their deposition, and the agglomeration reduces the durability of the device. However, according to this embodiment, the metal nano particles 2a do not agglomerate. Hence, also from this viewpoint, the light-emitting element 10 finally obtained can improve in durability.

Thus, this embodiment can provide the light-emitting element 10 higher in emission efficiency, durability, and balance of the carriers than a conventional light-emitting element, without raising the drive voltage.

A conductive polymeric material having n conjugation and a carbon main chain is thermally decomposed at a temperature of typically 100 to 300° C. Meanwhile, metal oxide semiconductor is extremely high in thermal decomposition temperature. Moreover, PSQ having a stable functional group such as a methyl group or a phenyl group has a thermal decomposition temperature of 400° C. In this embodiment, a composite containing PSQ and nano particles of metal oxide semiconductor is used as a carrier-transport layer. Such a feature can provide the light-emitting element 10 with excellent heat resistance.

Described below with reference to Examples and Comparative Examples are the above advantageous effects in more detail.

Note that, in any of Examples 1 and 2 and Comparative Examples 2 and 3 below, 5 wt % of a commercially available ZnO ethanol fluid disperse (made by AVANTAMA) was used as a fluid disperse whose solvent contained metal oxide nano particles. The 5 wt % ZnO ethanol fluid disperse had ethanol containing 5 wt % of nano particles whose diameter was 12 nm. The color of the ethanol fluid disperse was brownish transparent.

### Example 1

In Example 1, PSQ after dehydration condensation reaction was PPSQ. A mixture liquid containing ZnO nano particles and phenyltrimethoxysilane was prepared, so that the concentration of PPSQ was 1 wt % with respect to the ethanol solvent. That is, a weight ratio of the ZnO nano particles to PPSQ after the ETL material had cured was approximately 5:1 in Example 1. Moreover, as described above, the PSQ precursor to be used was phenyltrimethoxysilane. For hydrolysis, water equal in molar amount to a methoxy group of phenyltrimethoxysilane and a little amount (catalyst amount) of formic acid as a catalyst were used.

Specifically, with respect to 2 ml of the 5 wt % ZnO ethanol fluid disperse, 0.12 mmol of phenyltrimethoxysilane, 6.5 μl (0.36 mmol) of water, and 1.2 ml of formic acid were mixed together in the atmosphere in a reaction container. Next, the reaction container was sealed. The mixture liquid in the reaction container was maintained at a temperature of 50° C., and stirred for 18 hours. Hence, hydrolysis of phenyltrimethoxysilane was promoted. After that, the reaction container was opened, and ethanol was delivered appropriately in the form of droplets. While the concentration of the ZnO nano particles and the concentrations of PSQ and a compound serving as the precursor of PSQ were maintained, the mixture liquid was stirred at a temperature of 50° C. for six hours. Hence, the formic acid and water were evaporated, and the dehydration condensation reaction was promoted. Hence, the ZnO nano particles and at least one of phenyltrimethoxysilane or molecules of condensed phenyltrimethoxysilane underwent sol-gel reaction to form a brownish-transparent mixture liquid (sol) serving as an ETL material (a carrier-transport material).

Next, on a silicon substrate, 5 μl of the ETL material was delivered in three droplets. The silicon substrate was heated on a hot plate at a temperature of 300° C. for 30 minutes. Hence, the dehydration condensation reaction was finished, and the sol was transformed to a gel. Moreover, the solvent was completely removed, and the gel was solidified. Thus, on the silicon substrate, a mixture film containing PPSQ and the ZnO nano particles was formed. In the mixture film the ZnO nano particles were coated with PPSQ. After that, a Fourier transform infrared spectrometer (FTIR) was used to measure a transmittance of the mixture film the infrared region.

### Example 2

In Example 2, a mixture liquid containing ZnO nano particles and phenyltrimethoxysilane was prepared, so that the concentration of PPSQ after the dehydration condensation reaction was 5 wt % with respect to the ethanol solvent. That is, a ratio of the ZnO nano particles and PPSQ after the ETL material had cured was approximately 1:1 in Example 2. Moreover, as can be seen in Example 1, the PSQ precursor to be used was phenyltrimethoxysilane. For hydrolysis, water equal in molar amount to a methoxy group of phenyltrimethoxysilane and a little amount (catalyst amount) of formic acid as a catalyst were used.

Specifically, with respect to 2 ml of the 5 wt % ZnO ethanol fluid disperse, 0.6 mmol of phenyltrimethoxysilane, 32.4 μl (1.8 mmol) of water, and 6.0 ml of formic acid were mixed together in the atmosphere in a reaction container. Next, the reactions were induced and the works were conducted under the same conditions as those of Example 1. The ZnO nano particles and at least one of phenyltrimethoxysilane or molecules of condensed phenyltrimethoxysilane underwent sol-gel reaction to form a brownish-transparent mixture liquid (sol) serving as an ETL material.

After that, as seen in Example 1, on a silicon substrate, 5 μl of the ETL material was delivered in three droplets. The silicon substrate was heated on a hot plate at a temperature of 300° C. for 30 minutes. Thus, on the silicon substrate, a mixture film containing PPSQ and the ZnO nano particles was formed. In the mixture film, the ZnO nano particles were coated with PPSQ. The mixture film was the same in thickness as the mixture film in Example 1. After that, the same technique used in Example 1 was used to measure a transmittance of the mixture film in the infrared region.

### Comparative Example 1

In this Comparative Example, the ethanol fluid contained 5 wt % of phenyltrimethoxysilane instead of 5 wt % of the ZnO ethanol fluid disperse. Then, the reactions were induced and the works were conducted under the same conditions as those of Example 2, except that no ZnO nano particles were used. A colorless and transparent solution (sol) was prepared. In the preparation of the solution, only phenyltrimethoxysilane underwent sol-gel reaction.

After that, as seen in Example 1, on a silicon substrate, 5 μl of the obtained solution was delivered in three droplets. The silicon substrate was heated on a hot plate at a temperature of 300° C. for 30 minutes. Hence, on the silicon substrate, a PPSQ film was formed of PPSQ. The PPSQ film was the same in thickness as the mixture film in Example 1. After that, the same technique used in Example 1 was used to measure a transmittance of the PPSQ film in the infrared region.

### Comparative Example 2

On a silicon substrate, 5 μl of the 5 wt % ZnO ethanol fluid disperse was delivered in three droplets. The silicon substrate was heated on a hot plate at a temperature of 300° C. for 30 minutes. Hence, on the silicon substrate, a ZnO film was formed of the deposited ZnO nano particles. The ZnO film was the same in thickness as the mixture film in Example 1. After that, the same technique used in Example 1 was used to measure a transmittance of the ZnO film in the infrared region.

### Comparative Example 3

In Comparative Example 3, the reactions were induced and the works were conducted under the same conditions as those of Example 2, except that phenyltrimethoxysilane was replaced with tetraethoxysilane, and, for hydrolysis, water to be used was equal in molar amount to an ethoxy group of tetraethoxysilane.

Specifically, with respect to 2 ml of the 5 wt. % ZnO ethanol fluid disperse, 0.6 mmol of tetraethoxysilane, 43.2 μl (2.4 mmol) of water, and 6.0 ml of formic acid were mixed together in the atmosphere in a reaction container. Next, the reactions were induced and the works were conducted under the same conditions as those of Example 1. The ZnO nano particles and at least one of tetraethoxysilane or molecules of condensed tetraethoxysilane underwent sol-gel reaction to form a brownish dispersion mixture liquid (sol) serving as an ETL material.

After that, as seen in Example 1, on a silicon substrate, 5 μl of the ETL material was delivered in three droplets. The silicon substrate was heated on a hot plate at a temperature of 300° C. for 30 minutes. Thus, on the silicon substrate, a mixture film containing silica (SiO₂) and the ZnO nano particles was formed. In the mixture film, the ZnO nano particles were coated with silica. The mixture film was the same in thickness as the mixture film in Example 1.

Note that the hydrolysis of tetraethoxysilane is represented by Si(OC₂H₅)₄+4H₂O→Si(OH)₄+4C₂H₅OH. Moreover, dehydration condensation reaction of silicic acid (Si(OH)₄) obtained by the hydrolysis of tetraethoxysilane is represented by Si(OH)₄— SiO₂+2H₂O. After that, the same technique used in Example 1 was used to measure a transmittance of the mixture film in the infrared region.

Table 1 collectively shows each of the materials used in Examples 1 and 2 and in Comparative Examples 1 to 3, and a condition of each of the liquids after the sol-gel reaction. The liquids were used in Examples 1 and 2, and Comparative Examples 1 to 3 for the deposition of the films.

TABLE 1

| | ZnO Nanoparticle | | | Catalyst | Condition of Liquid |
|---|---|---|---|---|---|
| | Solution | Alkoxysilane | Water | (Formic Acid) | after Sol-Gel Reaction |
| Example 1 | 2 ml of 5 wt % ZnO | 0.12 mmol of | 0.36 mmol | 1.2 μl | Brownish |
| | Ethanol Solution | Phenyltrimethoxysilane | 6.5 μl | | Transparent |
| Example 2 | 2 ml of 5 wt % ZnO | 0.6 mmol of | 1.8 mmol | 6.0 μl | Brownish |
| | Ethanol Solution | Phenyltrimethoxysilane | 32.4 μl | | Transparent |
| Comparative | 2 ml of 5 wt % ZnO | None | None | None | Brownish |
| Example 1 | Ethanol Solution | | | | Transparent |
| Comparative | None | 0.6 mmol of | 1.8 mmol | 6.0 μl | Colorless and |
| Example 2 | | Phenyltrimethoxysilane | 32.4 μl | | Transparent |
| Comparative | 2 ml of 5 wt % ZnO | 0.6 mmol of | 2.4 mmol | 6.0 μl | Brownish |
| Example 3 | Ethanol Solution | Tetraethoxysilane | 43.2 μl | | Transparent |

Moreover, FIG. 10 is a graph showing FTIR spectra of the films formed in Examples 1 and 2 and Comparative Examples 1 to 3.

Absorption peaks near 500 cm⁻¹ in the FTIR spectra are those of ZnO. Absorption peaks near 700 to 800 cm⁻¹ and 1500 cm⁻¹ are those of PSQ. The hydroxy group (—OH group) has an absorption band near 3200 to 3600 cm⁻¹.

The film obtained in Comparative Example 2 and made of genuine ZnO nano particles still has an absorption band of 3200 to 3600 cm⁻¹ even after the heating at 300° C. This is probably because of the hydroxy groups on the surface of the ZnO nano particles.

In contrast, the film obtained in Comparative Example 1 and formed of PSQ rarely exhibits absorption in 3200 to 3600 cm⁻¹. In Examples 1 and 2, the absorption in 3200 to 3600 cm⁻¹ decreases.

As described above, in Examples 1 and 2 and Comparative Examples 2 and 3, the thickness of the film formed on the silicon substrate and the concentration of the ZnO nano particles are adjusted to remain constant. Hence, fluctuations of light absorbance in 3200˜3600 cm⁻¹ show fluctuations of the amount of the hydroxy groups on the surface of the ZnO nano particles, which indicates chemical reaction of the hydroxy groups on the surface of the ZnO nano particles.

The FTIR spectra in FIG. 10 show that the films obtained in Examples 1 and 2 include ZnO and PSQ, and do not include hydroxy groups. Moreover, as described before in Example 1, a weight ratio of PSQ to the ZnO nano particles is ⅕. Hence, the weight ratio of PSQ to the ZnO nano particles is ⅕ of that of Example 2. Thus, in Example 1, the peak of PSQ is weak for the smaller weight ratio. However, the FTIR spectra in FIG. 10 show that, even if the weight ratio of PSQ to the ZnO nano particles is ⅕, the hydroxy groups are almost completely removed.

Meanwhile, Comparative Example 3 exhibits an increase in light absorbance in 3200-3600 cm⁻¹. This is probably because tetraalkoxysilane, which is a precursor of silica, chemically bonds to hydroxy groups on the surface of metal oxide nano particles as trialkoxysilane does so; whereas, hydroxy groups derived from silica do not bond and remain.

As illustrated in FIG. 10, the hydroxy groups in Examples 1 and 2 are small in amount, and are suitable to a carrier-transport layer directly in contact with the EML 3.

Moreover, according to the Lambert-Beer law, an equation below is used to calculate a light absorbance of an absorption band of a hydroxy group in a film obtained in each of Examples 1 and 2 and Comparative Examples 1 to 3, and a reduction rate of the light absorbance is indicated.

[Light Absorbance]=−log₁₀[Transmittance]=[Light Absorbance Coefficient]×[Thickness]×[Concentration of Specimen]

Note that, wherein, [Transmittance], [Light Absorbance Coefficient], and [Thickness]respectively indicate[Transmittance], [Light Absorbance Coefficient], and [Thickness] of the films formed in Examples 1 and 2 and Comparative Examples 1 to 3. Moreover, [Concentration of Specimen] indicates a concentration of the ZnO nano particles in each of the liquids used for depositing the films in Examples 1 and 2 and Comparative Examples 1 to 3.

Table 2 shows an average transmittance in 3200 to 3600 cm¹ for each of the films obtained in Examples 1 and 2 and Comparative Examples 1 to 3, and a reduction rate of the light absorbance compared with that in Comparative Example 2.

TABLE 2

| | | Reduction Rate of Light |
|---|---|---|
| | Average Transmittance | Absorbance Compared with |
| | in 3200 to 3600 cm⁻¹ | That in Comparative Example 2 |
| Example 1 | 88.4 | −54% |
| Example 2 | 98.3 | −94% |
| Comparative | 99.7 | — |
| Example 1 | | |
| Comparative | 76.4 | — |
| Example 2 | | |
| Comparative | 65.1 | +60% |
| Example 3 | | |

If the film has a hydroxy group, the transmittance decreases. If no hydroxy group is found, the transmittance is close to 100%. The results in Table 2 show that the transmittance is higher in Examples 1 and 2 than in Comparative Example 2, and the hydroxy groups disappear. Moreover, the results in Table 2 show that the hydroxy groups increase by approximately 60% in Comparative Example 3 than in Comparative Example 2.

Furthermore, the film deposition and the durability and heat resistance were compared between the cases where the carrier-transport layer was made of ZnO alone, of a mixture film containing ZnO and an organic polymer, of a mixture film containing ZnO and silica, and of a mixture film containing a composite of ZnO and PSQ. Table 3 shows the results together with the presence or absence of remaining hydroxy groups in each of the cases.

Note that the organic polymer was PVP, as seen in Patent Document 2. Moreover, PSQ was PPSQ as an example. The film deposition was evaluated with a stylus profiler. The durability and heat resistance were evaluated by thermogravimetric analysis.

Furthermore, in Table 3, the signs “Good”, “Fair”, and “Poor” for the film deposition respectively denote that the surface roughness (RMS) of a deposited mixture film is “2 nm or less”, “2 to 20 nm”, and “20 nm or more”. Moreover, the signs “Good”, “Fair”, and “Poor” for the durability and heat resistance respectively denote that the temperature to start thermal decomposition is “400° C. or above”, “200 to 400° C.”. and “200° C. or below”.

TABLE 3

| | | | Remaining |
|---|---|---|---|
| | Film | Durability and | Hydroxy |
| | Deposition | Heat Resistance | Groups |
| ZnO Alone | Fair | Good | Yes |
| ZnO/Organic Polymer | Good | Fair | Yes |
| ZnO/Silica | Poor | Good | Yes |
| ZnO/PSQ | Good | Good | Almost None |

Table 3 shows that, when the carrier-transport layer is made of ZnO alone as seen in Comparative Example 2 and Non-Patent Document 1, and when the carrier-transport layer is made of a mixture film containing ZnO and silica as seen in Comparative Example 3, the film deposition is not good. Moreover, as seen in Table 3, when the carrier-transport layer is made of a mixture film containing ZnO and an organic polymer as seen in Patent Document 2, durability and heat resistance are not good. Furthermore, as seen in Table 3, when the carrier-transport layer is made of ZnO alone, of a mixture film containing ZnO and an organic polymer, or of a mixture film containing ZnO and silica, any of the cases shows that hydroxy groups remain on the surface of ZnO. Whereas, as seen in Table 3, when the carrier-transport layer is made of a mixture film containing a composite of ZnO and PSQ as described in this embodiment, the film deposition and the durability and heat resistance are good. Hence, the light-emitting element 10 to be produced can include a carrier-transport layer that rarely has remaining hydroxy groups.

Volume Rate of Metal Oxide Nano Particles 2a to Mixture Film

Next, described below is a volume rate of the metal oxide nano particles 2a to the mixture film, with reference to FIGS. 1 and 11.

The volumes of the metal oxide nano particles 2a and the polymer 2b can be obtained by dividing the weights of the metal oxide nano particles 2a and the polymer 2b in the mixture liquid by their respective densities (a weight per unit volume). For example, the density of PPSQ is 1.56 g/cm³, and the density of ZnO is 5.61 g/cm³.

Here, it is assumed that the sum of the volumes of semiconductor nano particles such as the metal oxide nano particles and a polymer is a volume of the mixture film made of the semiconductor nano particles and the polymer, and that the semiconductor nano particles disperse uniformly in the mixture film. In such a case, the median inter-nanoparticle distance between the semiconductor nano particles (hereinafter referred to as an “inter-nanoparticle distance”) in the mixture film is represented approximately as shown in FIG. 11.

The inter-nanoparticle distance represents a value obtained by subtracting the median particle size of the semiconductor nano particles from the median particle center distance between the semiconductor nano particles. The median particle center distance between the semiconductor nano particles can be measured with a TEM or by small angle X-ray scattering of a film containing semiconductor nano particles. The median particle size of the semiconductor nano particles can be measured by dynamic light scattering or with a TEM, as described before. The median particle size of the semiconductor nano particles is a diameter of the semiconductor nano particles at 50% of an integrated value in the particle size distribution, as described before.

Moreover, in FIG. 11, the “NANO PARTICLE VOLUME/MIXTURE FILM VOLUME” represents a volume rate of the semiconductor nano particles to the mixture film. In FIG. 11, the “SEMICONDUCTOR NANO PARTICLE SIZE” represents the “median particle size of the semiconductor nano particles”.

Note that, if the semiconductor nano particles are spherical, gaps appear even in a hexagonal close-packed structure. The volume of the semiconductor nano particles to the volume of the mixture film is approximately 74% at maximum (the semiconductor nano particles are in contact with one another) if the volume of the mixture film contains the volume of the gaps. FIG. 11 shows a graph in which the volume of the gaps is subtracted from the volume of the mixture film.

In an integrated film of the semiconductor nano particles, the carriers move by hopping conduction due to tunneling. A tunneling current between the semiconductor nano particles covered with an insulator is more likely to be generated as the inter-nanoparticle distance is shorter. More specifically, the tunneling current is generated typically when the inter-nanoparticle distance is 3 nm or less. Moreover, the tunneling current is likely to be generated particularly when the inter-nanoparticle distance is 1.5 nm or less.

PSQ serves as an insulator with a large bandgap when the organic group (R) is such an organic group as a methyl group that does not have a n-conjugated electron. Hence, a PSQ thin film cannot be used as a carrier-transport material. However, as described above, a composite of the semiconductor nano particles and PSQ can be used as a carrier-transport material.

In FIG. 11, the semiconductor nano particles are ZnO nano particles. The “median inter-nanoparticle distance between the semiconductor nano particles” or the “inter-nanoparticle distance” can be interpreted as the “median inter-nanoparticle distance between the metal oxide nano particles (i.e. the median inter-nanoparticle distance between fine particles, of the metal oxide, adjacent to one another)”. Hence, FIG. 11 shows a relationship between: the volume rate of the metal oxide nano particles 2a to the mixture film forming the ETL 2 and containing the metal oxide nano particles 2a and the polymer 2b; and the median inter-nanoparticle distance between the metal oxide nano particles in the mixture film. Moreover, the “inter-nanoparticle distance (i.e. the median inter-nanoparticle distance between the semiconductor nano particles)” in FIG. 11 is equivalent to a distance d1 between metal oxide nano particles adjacent to one another.

FIG. 11 shows a result of substantial calculation indicating how much volume rate of the semiconductor nano particles to the mixture film of the semiconductor nano particles and PSQ determines how much median distance between the semiconductor particles adjacent to one another in the mixture film of the semiconductor nano particles and PSQ. Hence, FIG. 11 shows that how much amount of PSQ coating the semiconductor nano particles determines how much median distance between the semiconductor nano particles adjacent to one another.

As described before, the tunneling current is generated particularly when the inter-nanoparticle distance is 3 nm or less. Hence, if the mixture film allows the carriers to move, the inter-nanoparticle distance has to be 3 nm or less. As shown in FIG. 11, if the inter-nanoparticle distance is set to 3 nm or less, the volume rate of the semiconductor nano particles to the mixture film (i.e. the carrier-transport layer made of the mixture film) is preferably 15% or more, and more preferably 30% or more.

Meanwhile, if the volume rate of the semiconductor nano particles to the mixture film is large, the hydroxy groups on the surface of the semiconductor nano particles fail to react and remain. Hence, the volume rate of the semiconductor nano particles to the mixture film is preferably 90/o or less, and, more preferably, 80% or less.

Hence, the volume rate of the metal oxide nano particles 2a to the mixture film (i.e. the ETL 2) is preferably 15% or more and 90% or less. Moreover, a lower limit of the volume rate of the metal oxide nano particles 2a to the mixture film is preferably 30%, and, more preferably, 80%.

When the rate is 90% or less, the amount of remaining hydroxy groups can be reduced; whereas, when the rate is 15% or more, excellent carrier mobility (in this embodiment, electron mobility) can be achieved.

Furthermore, in the ETL 2, the distance d1 between the metal oxide nano particles 2a adjacent to one another (the median inter-nanoparticle distance between the metal oxide nano particles) is preferably 3 nm or less, and, more preferably, 1.5 nm or less because of the reasons described before.

(Modification 1)

Note that this embodiment exemplifies a case where the EML 3 is a quantum-dot light-emitting layer containing quantum dots as a light-emitting material.

As to a conventional light-emitting element including a quantum-dot light-emitting layer, if the carrier-transport layer contains metal oxide nano particles, the light-emitting element exhibits significant deactivation of the quantum dots caused by hydroxy groups on the surface of the metal oxide nano particles. However, this embodiment can prevent the deactivation of these quantum dots.

However, the EML 3 shall not be limited to a quantum-dot light-emitting layer. The EML 3 may contain, for example, an organic light-emitting material that emits light in various colors, instead of the quantum dots.

If the light-emitting element 10 is a QLED containing quantum dots as the light-emitting material, the electrons and the holes recombine together in the EML 3 by a drive current between the cathode 1 and the anode 5. Then, the recombination forms an exciton. While the exciton transforms from the conduction band level to the valence band level of the quantum dots, light (fluorescence) is released.

Meanwhile, if the light-emitting element 10 is an OLED containing an organic light-emitting material as the light-emitting material, the electron and the holes recombine together in the EML 3 by a drive current between the cathode 1 and the anode 5, which forms an exciton. While the exciton transforms to the ground state, light is released.

Moreover, the light-emitting element 10 may be a light-emitting element (e.g. an inorganic light-emitting diode) other than the OLED and the QLED.

Furthermore, FIG. 1 exemplifies a case where the light-emitting element 10 includes the HTL 4. However, the light-emitting element 10 shall not be limited to the configuration exemplified in FIG. 1. The light-emitting element 10 may omit the HTL 4. In addition, between the anode 5 and the EML 3, an HIL and the HTL 4 may be provided in this order from toward the anode 5, as intermediate layers between the anode 5 and the EMIL 3. Moreover, between the cathode 1 and the ETL 2, for example, an EIL may be separately provided as an intermediate layer between the cathode 1 and the ETL 2.

(Modification 2)

FIG. 1 exemplifies a case where the metal oxide nano particles 2a are covered with the polymer 2b throughout the ETL 2.

However, in the light-emitting element 10, the metal oxide nano particles 2a do not have to be covered with the polymer 2b throughout the carrier-transport layer. In the light-emitting element 10, the metal oxide nano particles 2a only have to be covered with the polymer 2b on the interface between the carrier-transport layer and the light-emitting layer 3.

Thus, for example, when the metal oxide nano particles 2a may be applied to a position in which the carrier-transport layer is to be formed. After that, to the metal oxide nano particles 2a, metal oxide nano particles 2a whose surface is covered with the polymer 2b may be applied.

### Second Embodiment

In this embodiment, a difference from the first embodiment will be described. Note that, for the sake of description, like reference signs designate constituent features with identical functions between this embodiment and the first embodiment. Such constituent features will not be elaborated upon here.

The first embodiment exemplifies a case where the first electrode is the cathode 1, the second electrode is the anode 5, and the first carrier-transport layer is the ETL 2. This embodiment exemplifies a case where the first electrode is the anode 5, the second electrode is the cathode 1, and the first carrier-transport layer is the HTL 4.

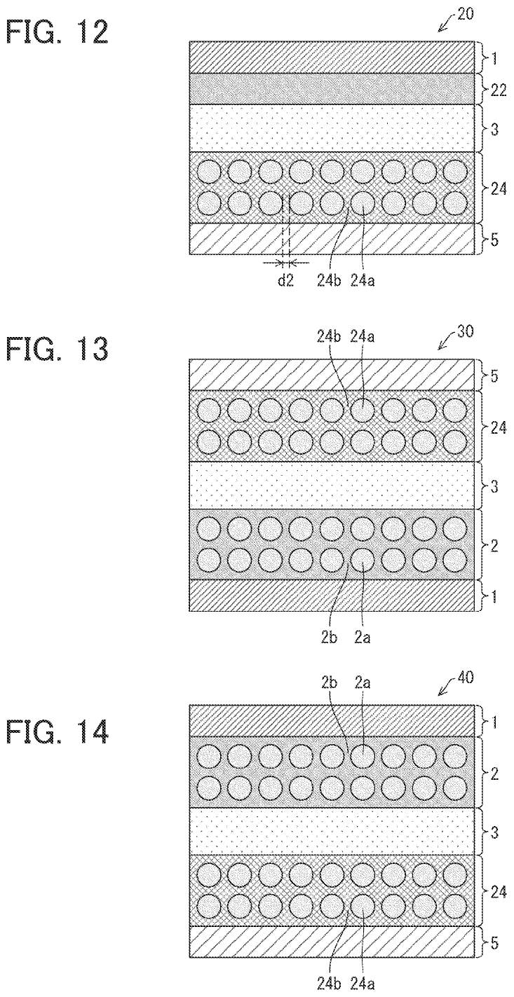

FIG. 12 is a cross-sectional view illustrating an exemplary schematic configuration of a light-emitting element 20 according to this embodiment.

As illustrated in FIG. 12, the light-emitting element 20 according to this embodiment includes: the anode 5; an HTL 24; the EML 3; and the cathode 1, all of which are stacked one another in this order from below. As illustrated in FIG. 12, between the EML 3 and the cathode 1; that is, the second electrode, the ETL 22 may be provided as the second carrier-transport layer.

Note that, in the example in FIG. 12, the anode 5 is a lower electrode provided below, and the cathode 1 is an upper electrode provided above. Hence, in this embodiment, a direction from the cathode 5 toward the anode 1 is referred to as the upward direction, and a direction opposite to the upward direction is referred to as the downward direction.

In this embodiment, the cathode 1 injects electrons through the ETL 22 into the EML 3. Meanwhile, the cathode 5 injects holes through the HTL 24 into the EML 3.

The ETL 22 is a layer to transport the electrons to the EML 3. Note that the ETL 22 may also function to block transportation of the holes.

The ETL 22 contains an electron-transporting material. In this embodiment, the electron-transporting material is either an organic electron-transporting material or a metal complex. Examples of the organic electron-transporting material can include: oxadiazoles; triazoles; phenanthrolines; a silole derivative; a cyclopentadiene derivative; and an aluminum complex. Specifically, the oxadiazole derivative includes 2-(4-biphenylyl)-5-(4-tert-butylphenyl)-1,3,4-oxadiazole (PBD). The phenanthrolines include: batho-cuproine (BCP) and batho-phenanthroline (BPhen). The aluminum complex includes: a tris(8-quinolinol) aluminium complex (Alq 3); and a bis(2-methyl-8-quinolinatoxp-phenylphenolate) aluminum complex (BAlq). One of these electron-transporting materials may be used alone, or two or more of these electron-transporting materials may be used in combination as appropriate.

The HTL 24 is a layer to transport the holes to the EML 3. The HTL 24 is provided in contact with the EML 3. Note that the HTL 24 may also function to block transportation of the electrons.

The HTL 24 contains metal oxide nano particles 24a (fine particles of metal oxide) that transport carriers, and a polymer 24b chemically bonding to the metal oxide nano particles 24a.

The metal oxide includes the metal oxide exemplified in the first embodiment. One of these metal oxides may be used alone, or two or more kinds of these metal oxides may be used in combination as appropriate.

Moreover, the metal oxide nano particles 24a shall not be limited to particular nano particles in terms of shape and size. However, preferably, the metal oxide nano particles 24a may have a spherical shape and a median particle size (a diameter) ranging from 0.5 to 20 nm because of the same reason for the metal oxide nano particles 4a.

Furthermore, the polymer 24b can be the same polymer as the polymer 2b described in the first embodiment. Hence, in the first embodiment, the “metal oxide nano particles 2a” and the “polymer 2b” can be respectively interpreted as the “metal oxide nano particles 24a” and the “polymer 24b”.

In addition, in the first embodiment, the “cathode 1”, the “ETL 2”, the “HTL 4”, the “anode 5”, the “EIL”, and the “HIL” can be sequentially interpreted as the “anode 5”, the “HTL 24”, the “ETL 22”, the “cathode 1”, the “HIL”, and the “EIL” except for descriptions for the examples of those materials. Moreover, the “light-emitting element 10”, the “holes”, and the “electrons” may be sequentially interpreted as the “light-emitting element 20”, the “electrons”, and the “holes”. Moreover, the “distance d1 between the metal oxide nano particles 2a adjacent to one another” can be interpreted as a “distance d2 between metal oxide nano particles 24a adjacent to one another”.

Note that, in this embodiment, as described before, the ETL 22 is made of the electron-transporting material described before.

Moreover, in this embodiment, the metal oxide nano particles 24a are preferably wide-gap metal oxide nano particles capable of transporting holes. Hence, the metal oxide nano particles 24a are preferably nano particles of: such metal oxides as nickel oxide, copper oxide, molybdenum oxide, tungsten oxide, and indium oxide among the above metal oxides; a mixed crystal of these metal oxides; or a metal oxide formed of these metal oxides doped with another metal element. Note that the nano particles of such a metal oxide as nickel oxide, copper oxide, molybdenum oxide, tungsten oxide, or indium oxide doped with another metal element are those of such a metal oxide as indium tin oxide (ITO).

This embodiment can also achieve the same advantageous effects as those of the first embodiment.

### Third Embodiment

In this embodiment, a difference from the first and second embodiments will be described. Note that, for the sake of description, like reference signs designate constituent features with identical functions between this embodiment and the first and second embodiments. Such constituent features will not be elaborated upon here.

FIG. 13 is a cross-sectional view illustrating an exemplary schematic configuration of a light-emitting element 30 according to this embodiment.

As illustrated in FIG. 13, the light-emitting element 30 according to this embodiment includes: the cathode 1; the ETL 2; the EML 3; the HTL 24; and the anode 5, all of which are stacked one another in this order from below.

Note that, in the example in FIG. 13, the cathode 1 is a lower electrode provided below, and the anode 5 is an upper electrode provided above. Hence, in this embodiment, a direction from the cathode 1 toward the anode 5 is referred to as the upward direction, and a direction opposite to the upward direction is referred to as the downward direction.

The cathode 1, the ETL 2, the EML 3, the HTL 24, and the anode 5 in the stated order are the same as the cathode 1, the ETL 2, the EML 3, the HTL 24, and the anode 5 according to the first embodiment or the second embodiment. Specifically, the light-emitting element 30 according to this embodiment is the light-emitting element 10, according to the first embodiment, whose HTL 4 is replaced with the HTL 24 used in the second embodiment. Hence, this embodiment can achieve the same advantageous effects as those of the first and second embodiments.

### Fourth Embodiment

In this embodiment, a difference from the first to third embodiments will be described. Note that, for the sake of description, like reference signs designate constituent features with identical functions between this embodiment and the first to third embodiments. Such constituent features will not be elaborated upon here.

FIG. 14 is a cross-sectional view illustrating an exemplary schematic configuration of a light-emitting element 40 according to this embodiment.

As illustrated in FIG. 14, the light-emitting element 40 according to this embodiment includes: the anode 5; the HTL 24; the EML 3; the ETL 2; and the cathode 1, all of which are stacked one another in this order from below.

Note that, in the example in FIG. 14, the anode 5 is a lower electrode provided below, and the cathode 1 is an upper electrode provided above. Hence, in this embodiment, a direction from the cathode 5 toward the anode 1 is referred to as the upward direction, and a direction opposite to the upward direction is referred to as the downward direction.

The anode 5, the HTL 24, the EML 3, the ETL 2, and the cathode 1 in the stated order are the same as the anode 5, the HTL 24, the EML 3, the ETL 2, and the cathode 1 according to the first to third embodiments. Specifically, the light-emitting element 40 according to this embodiment is the light-emitting element 20, according to the second embodiment, whose ETL 2 is replaced with the ETL 2 used in the first embodiment. Hence, this embodiment can achieve the same advantageous effects as those of the first to third embodiments.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment may be combined to achieve a new technical feature.

### REFERENCE SIGNS LIST

1 Cathode (First Electrode or Second Electrode)
2 and 22 ETL (Carrier-Transport Layer)
2a and 24a Metal Oxide Nano Particles (Fine Particles of Metal
Oxide)
2b and 24b Polymer
3 EML (Light-Emitting Layer)
4 and 24 HTL (Carrier-Transport Layer)
Anode (First Electrode or Second Electrode)
10, 20, 30, and 40 Light-Emitting Element

1. A light-emitting element, comprising:
a first electrode and a second electrode;
a light-emitting layer provided between the first electrode and the second electrode; and
a carrier-transport layer provided between the first electrode and the light-emitting layer,
wherein the carrier-transport layer contains, on an interface at least to the light-emitting layer, fine particles of metal oxide and a polymer chemically bonding to a surface of the fine particles of the metal oxide,
the polymer contains a main chain of a polysiloxane bond and a side chain of an organic group and
the light-emitting layer is a quantum-dot light-emitting layer containing quantum dots, the light-emitting layer being in contact with the carrier-transport layer.

2. The light-emitting element according to claim 1,
wherein a volume rate of the metal oxide to the carrier-transport layer is 15% or more and 90% or less.

3. The light-emitting element according to claim 1,
wherein the polymer contains polysilsesquioxane.

4. The light-emitting element according to claim 1,
wherein the fine particles of the metal oxide contain fine particles of: at least one of metal oxides selected from the group consisting of zinc oxide, nickel oxide, magnesium oxide, copper oxide, molybdenum oxide, tin oxide, titanium oxide, vanadium oxide, tungsten oxide, niobium oxide, indium oxide, and cerium oxide; or a mixed crystal of the metal oxides.

5. (canceled)

6. The light-emitting element according to claim 1,
wherein the fine particles of the metal oxide has a particle size ranging from 0.5 to 20 nm,
the fine particles of the metal oxide are coated with the polymer, and
a median inter-nanoparticle distance between the fine particles, of the metal oxide, adjacent to one another is 3 nm or less.

7. The light-emitting element according to claim 1,
wherein the organic group is an organic group with 10 or less carbons.

8. A light-emitting element comprising
a first electrode and a second electrode;
a light-emitting layer provided between the first electrode and the second electrode; and
a carrier-transport layer provided between the first electrode and the light-emitting layer,
wherein the carrier-transport layer contains, on an interface at least to the light-emitting layer, fine particles of metal oxide and a polymer chemically bonding to a surface of the fine particles of the metal oxide,
the polymer contains a main chain of a polysiloxane bond and a side chain of an organic group,
the organic group is an organic group with 10 or less carbons, and
the organic group is at least one selected from the group consisting of an alkyl group, an aminoalkyl group, a mercaptoalkyl group, a vinylalkyl group, a fluoroalkyl group, an aryl group, and a heteroaryl group.

9. The light-emitting element according to claim 8,
wherein the organic group is an alkyl group or a phenyl group with one to five carbons.

10. A method for producing a light-emitting element, the method comprising:
a mixture liquid preparing step of causing fine particles of metal oxide and at least one of trialkoxysilane or molecules of condensed trialkoxysilane to undergo sol-gel reaction, to prepare a mixture liquid; and
a carrier-transport layer forming step of applying the mixture liquid to a position in which a carrier-transport layer is to be formed, to form the carrier-transport layer,
wherein, in the mixture liquid preparing step, the mixture liquid is heated at a temperature below 450° C. so that polymerization of at least one of the trialkoxysilane or the molecules of the condensed trialkoxysilane is promoted, and a polymer to be obtained is solidified.

11. The method for producing the light-emitting element according to claim 10,
wherein the mixture liquid further includes an acid catalyst.

12. (canceled)
